(19) United States
(12) Patent Application Publication
(10) Pub. No.: US 2021/0134566 A1
(43) Pub. Date: May 6, 2021

(54) SUBSTRATE MOUNT

(71) Applicant: Semblant Limited, London (GB)

(72) Inventors: Reynaldo CORPUZ CO, Santa Cruz, CA (US); Grant Sales VILLAVICENCIO, San Jose, CA (US); Ebrahim GHANBARI, San Ramon, CA (US)

(21) Appl. No.: 16/638,742

(22) PCT Filed: Aug. 15, 2018
(86) PCT No.: PCT/GB2018/052317

§ 371 Date: Feb. 12, 2020

(30) Foreign Application Priority Data
Aug. 17, 2017 (GB) 1713202.8

(51) Int. Cl. H01J 37/32

(52) U.S. Cl. CPC H01J 37/32715; H01J 2237/2007

(57) ABSTRACT

A substrate mount for a plasma processing apparatus comprising: a frame; an aperture within the frame, configured to accommodate an insert, the insert being configured to support a substrate for processing by the plasma processing apparatus; a releasable securing mechanism configured to releasably secure the insert within the aperture such that the insert can be replaced.

The present invention relates to a substrate mount for a plasma processing apparatus. In particular, the invention relates to a substrate mount having replaceable inserts for modifying the substrate mount to be suitable for use with different substrates.

Plasma processing may include: plasma deposition, plasma surface activation, plasma etching and plasma cleaning, for example. The type of processing is determined by the plasma species generated which is mainly controlled/tuned by the feed gas and or precursor used. Plasma deposition is a known method for providing conformal coatings to substrates, such as electronics. Plasma surface activation is a known method for changing the surface (e.g. energy) properties of a substrate. Plasma etching is a known method for etching patterns in a substrate, e.g. to fabricate integrated circuits. Plasma cleaning is a known method of removing material from the surface of a substrate.

Plasma processing apparatuses generally comprise a process chamber and a plasma source for providing a plasma within the process chamber. A substrate, e.g. PCB, is placed within the chamber and interacts with the plasma, thus, is processed. In the case of plasma deposition for example, a coating of material formed from the plasma is deposited on the substrate.

The substrate to be processed is supported in the chamber by a substrate mount. These are usually in the form of an aluminium shelf on which the substrates are placed. For some applications, coating is require on opposite sides of the substrate. Therefore, substrates may be held within an aperture in the substrate mount so as to expose both sides of the substrate. The shape of the aperture is specific to the substrate being coated. This is because the aperture needs to hold a substrate of a specific shape but also because certain areas of the substrate may need to be masked so as not to be processed. Typically, the substrate is located within a flexible rubber gasket glued to the metal substrate mount. The gasket acts as a mask.

Substrate mounts are manufactured specifically for a particular substrate. Therefore, different substrate mounts are needed for different substrates. This can be very costly as new substrate mounts need to be made for each different substrate or if a substrate design changes.

The present invention aims to at least partly solve the above problems.

Accordingly, a first aspect of the present invention provides a substrate mount for a plasma processing apparatus comprising: a frame; an aperture within the frame, configured to accommodate an insert, the insert being configured to support a substrate for processing by the plasma processing apparatus; a releasable securing mechanism configured to releasably secure the insert within the aperture such that the insert can be replaced.

Optionally, the frame is formed from a single part. Alternatively, optionally, the frame comprises first and second frame parts, the first and second frame parts being configured to sandwich the insert therebetween.

Optionally, the releasable securing mechanism is configured to releasably secure the first frame part to the second frame part.

Optionally, the releasable securing mechanism is configured to releasably secure the insert to the frame.

Optionally, the securing mechanism comprises a spring element configured to provide a securing force. Optionally, the securing mechanism comprises an abutment member configured to apply the securing force therethrough. Optionally, the abutment member is also the spring element. Optionally, the spring element is separate from but connected to the abutment member. Optionally, the spring element comprises at least one of a coil spring, a leaf spring and a plate spring.

Optionally, the releasable securing mechanism is selectably configurable between a first arrangement configured to secure the insert and a second arrangement configured not to secure the insert.

Optionally, the releasable securing mechanism is configured to rotate between the first arrangement and the second arrangement. Alternatively, optionally, the releasable securing mechanism is configured to slide linearly between the first arrangement and the second arrangement.

Optionally, the releasable securing mechanism comprises a snap-fit mechanism.

Optionally, the aperture comprises a shelf member configured to support the insert within the aperture.

Optionally, the aperture has a rectangular cross-section normal an axis passing through the aperture.

Optionally, the substrate mount comprises a plurality of identical apertures.

According to a second aspect of the invention there is provided an insert configured to be used with the substrate mount of the previous aspect, comprising an aperture for accommodating the substrate.

Optionally, the insert comprises a first insert part and a second insert part, the first and second insert parts being configured to sandwich the substrate therebetween.

Optionally, the insert comprises an alignment member configured to align the first and second insert parts and, optionally, the substrate. Optionally, the alignment member is a rod configured to pass through through-holes in each of the first and second insert parts and, optionally, the substrate.

Optionally, the insert comprises a mask formed from a first material and configured to support the substrate such that a portion of the substrate is masked so as not to be processed by the plasma processing apparatus. Optionally, the first material is a flexible material.

Optionally, the insert comprises an insert frame formed from a second material and configured to support the mask. Optionally, the second material is a rigid material.

A third aspect of the invention provides a substrate mount according to the first aspect further comprising the insert according to the second aspect.

A fourth aspect of the invention provides a kit of parts comprising at least one substrate mount according to the first aspect and at least one insert according to the second aspect.

A fifth aspect of the invention provides a plasma processing apparatus for processing a substrate with a plasma, comprising: a processing chamber in which the processing takes place; and at least one substrate mount according to the first aspect or the third aspect.

Further features and advantages of the invention will be described below by way of non-limiting example and with reference to the accompanying drawings, in which:

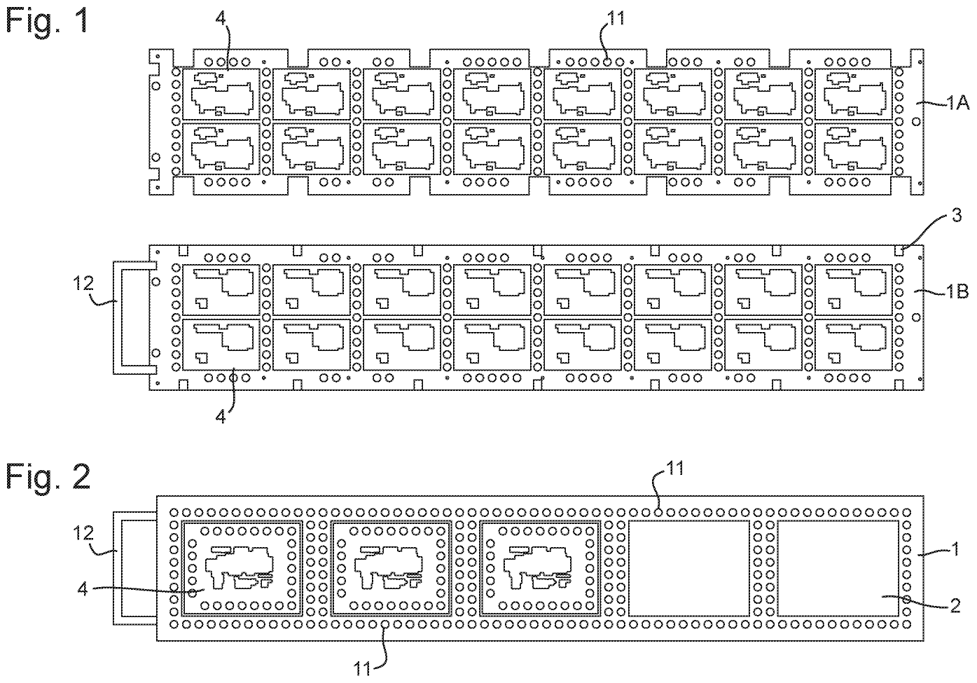

FIG. 1 shows a top view of a first substrate mount;

FIG. 2 shows a top view of a second substrate mount;

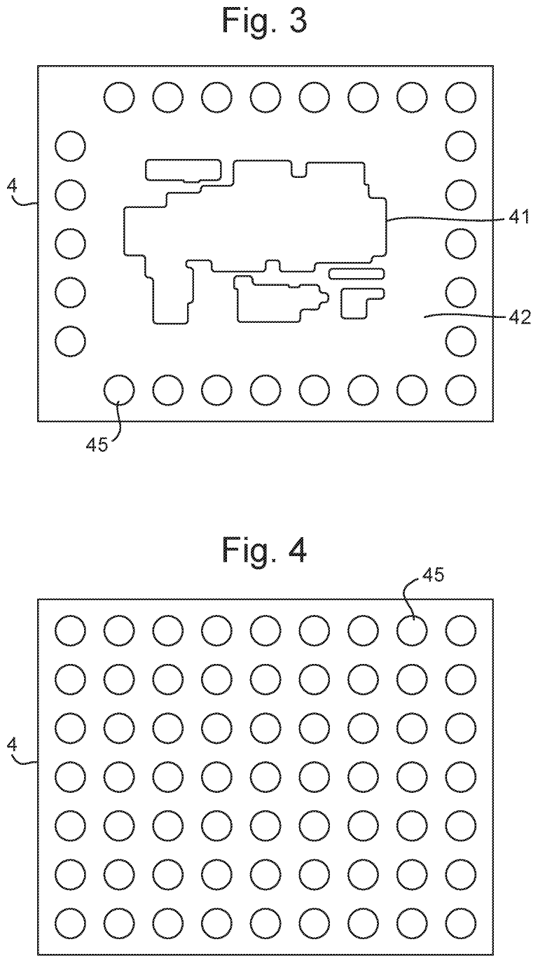

FIG. 3 shows a top view of a first insert;

FIG. 4 shows a top view of a second insert;

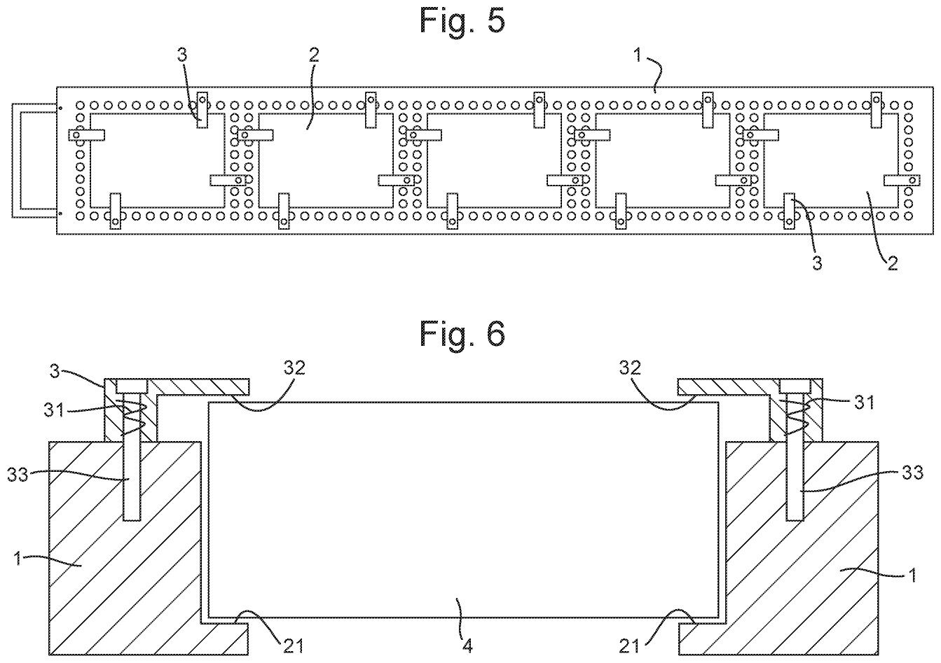

FIG. 5 shows a top view of the substrate mount of FIG. 2 in further detail;

FIG. 6 shows a side view of an example of a releasable securing mechanism;

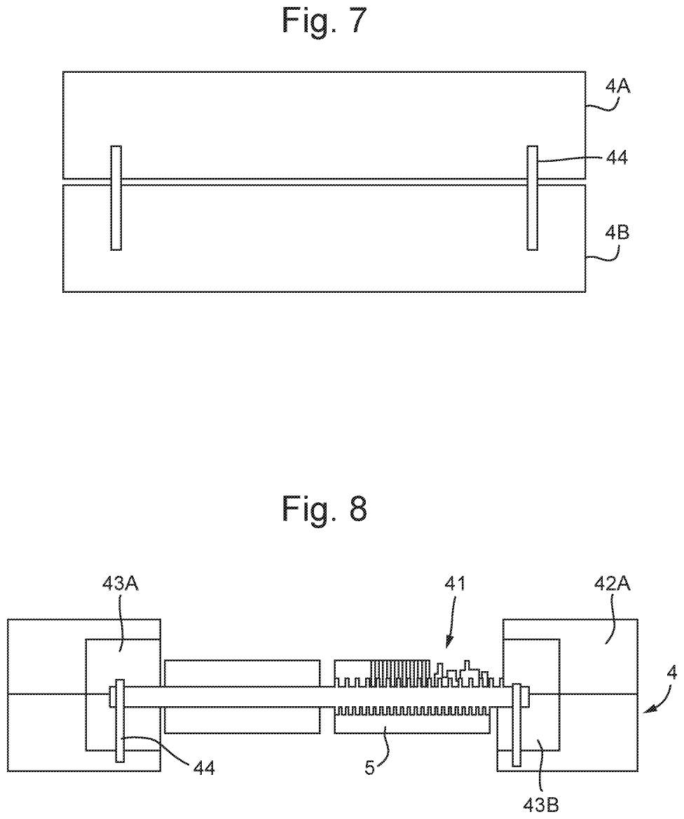

FIG. 7 show a side view of an insert;

FIG. 8 shows a side view of another insert;

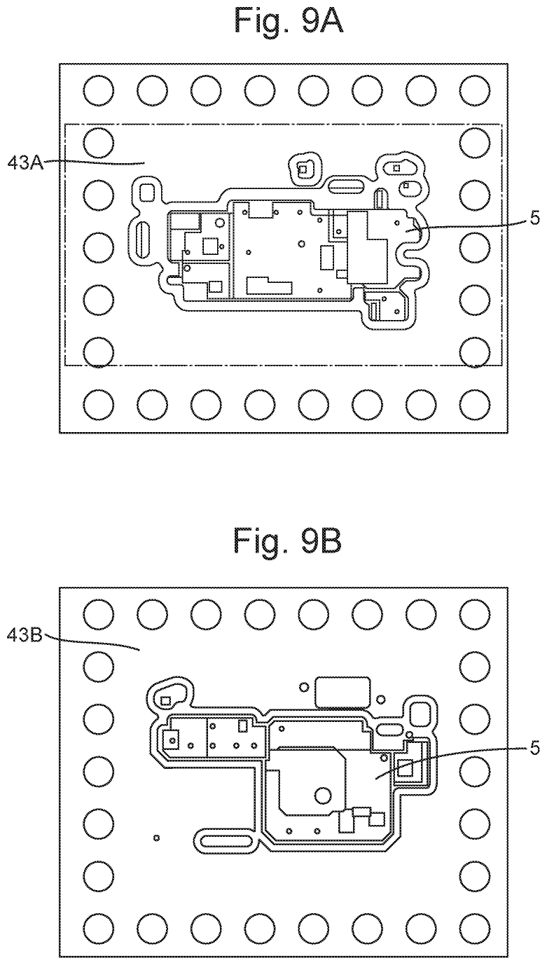

FIGS. 9A and 9B respectively show top and bottom views of a mask.

The present invention provides a substrate mount for a plasma processing apparatus, comprising: a frame 1; an aperture 2 within the frame 1, configured to accommodate an insert 4, the insert 4 being configured to support a substrate 5 for processing by the plasma processing apparatus; a releasable securing mechanism 3 configured to releasably secure the insert 4 within the aperture 2 such that the insert 4 can be replaced.

Accordingly, inserts 4 specific to particular substrates 5 can be replaced by different inserts 4 within the substrate mount, thus avoiding the costly practice of needing a different substrate mount for each different substrate or combination of substrates 5. In other words, the substrate mount of the invention is a universal substrate mount for use with any substrate 5 or combination of substrates 5.

FIG. 1 shows a substrate mount according to a first embodiment of the invention. In this embodiment, the frame 1 comprises first and second frame parts 1A, 1B, the first and second frame parts 1A, 1B are configured to sandwich the insert 4 therebetween. FIG. 1 shows the two parts 1A, 1B in their separated state. The aperture 2 is provided in each part 1A, 1B of the frame 1. As shown, the insert 4, in this case also provided in two parts, is placed within the aperture 2.

The first part 1A is placed on top of the second part 1B. FIG. 1 shows the two opposing surfaces of the frame parts 1A, 1B that meet when the frame parts 1A, 1B are put together. After the first part 1A is placed on top of the second part 1B, it is secured in place by a releasable securing mechanism 3. This secures the insert 4 within the frame 1 of the substrate mount. In other words, the releasable securing mechanism 3 may be configured to releasably secure the first frame part 1A to the second frame part 2A. In a variation of the first embodiment, the releasable securing mechanism 3 may alternatively or additionally be configured to releasably secure the insert 4 to the frame 1.

FIG. 2 shows a substrate mount according to a second embodiment of the invention. In this embodiment, the frame is formed from a single part, as opposed to first and second parts 1A, 1B. The insert 4 is placed in the aperture 2, through one side of the frame 1 e.g. the top. In this embodiment, the releasable securing mechanism 3 is configured to releasably secure the insert 4 to the frame 1. In other words, the insert, 4 is prevented from being removed from the aperture 2 by the releasable securing mechanism 3.

The frame 1 may be formed from a rigid material, preferably a metal, e.g. stainless steel, but preferably aluminium. In some cases, the frame 1 may be required to function as an electrode during plasma processing. The surface of the frame 1 comprises a plurality of through-holes 11, preferably circular in cross-section. These allow plasma to move from one side of the frame 1 to another and contribute to more uniform processing.

The frame 1 may include a handle 12 for removing the substrate mount from the plasma chamber.

Examples of the releasable securing mechanism 3 are described in further detail below. The same mechanisms may be used in both of the above embodiments. In other words, the mechanism 3 may be used for securing the first and second frame parts 1A, 1B together and/or securing the insert 4 to the frame 1. The type of mechanism 3 used is not particularly limited provided that it is releasable, i.e. the insert 4 can be easily removed from the frame 1, (preferably manually, without the need for a machine or tool). The mechanism 3 should, however, be suitable for use in a plasma processing apparatus. For example, the materials may be chosen to be compatible with the plasma processing. For example the mechanism 3 may be formed substantially from a metal, e.g. stainless steel or aluminium.

The releasable securing mechanism 3 may comprise a spring element 31 configured to provide a securing force. The securing force may act to press the first and second frame parts 1A, 1B together (as in the case of the first embodiment described above), and/or press the insert 4 and the frame 1 together (as in the case of the second embodiment described above). The spring element 31 may comprise at least one of a coil spring, a leaf spring and a plate spring, for example.

The releasable securing mechanism 3 may comprise an abutment member 32 configured to apply the securing force therethrough. In other words, the force generated by the spring element may be transferred through the abutment member 32.

In the first embodiment, the releasable securing mechanism 3 may be provided on the second frame part 1B, as shown in FIG. 1. The abutment member 32 may be configured to abut a portion of the first frame part 1A and transfer a force from the spring element 31 to the first frame part 1A so as to press the first and second frame parts 1A and 1B together.

In the second embodiment, the releasable securing mechanism 3 may be provided on the frame 1, as show in FIG. 5. The abutment member 32 may be configured to abut a portion of the insert 4 and transfer a force from the spring element 31 to the insert 4 so as to press the insert and the frame 1 together. In this case the insert is supported by a portion of the frame on the opposite side of the insert 4 to the releasable securing mechanism 3.

However, alternatively, releasable securing mechanism 3 may be provided on both sides of the insert 4 in the aperture 2.

In one example not shown, the abutment member 32 may also be the spring element 31. For example, the abutment member 32 may be formed from a resilient material configured to provide the securing force.

In another example, e.g. as shown in FIG. 6, the spring element 31 may be separate from but connected to the abutment member 32. Therefore, the securing force provided by the spring element 31 can be transferred to the abutment member 32.

As shown FIG. 6, the releasable securing mechanism 3 may comprise the spring element 31, the abutment member 32 and a shaft member 33. In this example, the abutment member 31 is arranged to slide up and down the shaft member. The shaft member 32 may be a cylindrical rod configured to engage with a corresponding recess (or through-hole) in the abutment member 32. The spring element 31 may be a coil spring, for example, and may be connected to the abutment member 32 at one end and to either the shaft member 33 or the frame 1 at the other end. Thus, the spring element 31 acts to pull the abutment member towards the frame to secure the insert 4 in the frame 1. Although the mechanism in FIG. 6 relates to the second embodiment, the same mechanism may be used in the first embodiment to secure the first and second frame parts 1A, 1B together (such a releasable securing mechanism 3 is shown in FIG. 1).

The releasable securing mechanism 3 may be selectably configurable between a first arrangement configured to secure the insert 4 and a second arrangement configured not to secure the insert 4.

In one example, the releasable securing mechanism 3 may configured to rotate between the first arrangement and the second arrangement. For example, as in the example shown in FIG. 6, the abutment part 32 may additionally be rotatable about the shaft member 21. The first selectable arrangement may be such that the abutment member abuts the insert 4 (as shown in FIG. 6). The second selectable arrangement may be such that the abutment member does not abut the insert 4 e.g. rotated more than 90 degrees relative to the first arrangement. The spring element 21 may additionally act as a torsion spring configured to provide a force that rotates the abutment member 32 about the shaft member 21, e.g. to bias the abutment member 32 towards the first selectable arrangement.

In another example, not shown in the drawings, the releasable securing mechanism 3 may be configured to slide linearly between the first arrangement and the second arrangement. For example, the securing mechanism 3 may be a sliding bolt.

Various other releasable securing mechanisms 3 may be used. For example, the releasable securing mechanism 3 may comprise a snap-fit mechanism. Alternatively, the releasable securing mechanism 3 may comprise a bolt, a screw, a latch, a clip or a screw clamp, for example.

Multiple releasable securing mechanisms 3 may be used to secure each insert 4 to the frame 1 or to secure the frame parts 1A, 1B together. The releasable securing mechanisms 3 are preferably arranged on the frame 1 so as not to partially block the through-holes 11 provided within the frame 1 and/or through holes 45 in the insert 4.

The releasable securing mechanisms 3 may be arranged around the aperture 2 so as to evenly distribute the securing force over the substrate. This ensures that the substrate is under minimal stress when processing occurs. Too much stress may lead to unsatisfactory processing. Releasable securing mechanisms 3 may be distributed symmetrically around the aperture 2. An axis of symmetry of the arrangement of releasable securing mechanisms 3 may be the same as an axis of symmetry of the aperture 2.

The aperture 2 of the frame 1 may comprises a shelf member 21 configured to support the insert 4 within the aperture 2. The shelf member 21 may be formed from a part of the frame 1. A shelf member 21 is shown in FIG. 2 The shelf member 21 may be formed by a relatively narrow portion of the aperture 2 such that the insert 4 is prevented from passing through the aperture beyond the location of the shelf member 21. Although the shelf member 21 in FIG. 6 comprises a flat surface on which the insert can rest, this is not essential, e.g. the surface may be sloped relative to a thickness direction of the frame 1.

In the case of the first embodiment, a shelf member 21 may be provided in each of the first and second frame parts 1A, 1B, e.g. closer to the outside surfaces of the constructed frame 1. In the case of the second embodiment, a single shelf member 21 is provided e.g. on an opposite side of the frame 1 from the releasable securing mechanism 3.

The aperture 2 may be any shape. However, preferably the aperture 2 has a rectangular cross-section normal to an axis passing through the aperture in a thickened direction of the frame 1. Preferably, a plurality of identical apertures 4 are provided in the frame 1.

As shown in FIG. 3 an insert 4 in accordance with the present invention may comprise an aperture 41 for accommodating the substrate 5. The aperture 41 of the insert 4 allows two opposing sides of the substrate 5 to be processed simultaneously. As shown in FIG. 7, the insert 4 may comprise a first insert part 4A and a second insert part 4B, the first and second insert parts 4A, 4B may be configured to sandwich the substrate 5 therebetween, as shown in FIG. 8. As shown in FIGS. 7 and 8, the insert may comprise an alignment member 44 configured to align the first and second insert parts 4A, 4B and, optionally, the substrate 5. The alignment member 44 may be a rod configured to pass through through-holes in each of the first and second insert parts 4A, 4B and, optionally, the substrate 5 to align them.

As shown in Fig., the insert 4 may comprise a mask 43 formed from a first material and configured to support the substrate 5 such that a portion of the substrates is masked so as not to be processed by the plasma processing apparatus. The first material may a flexible material. For example, the first material may be one of Flourosilicone, Hypalon, Natural (Gum) Rubber, Neoprene, Nitrile Buna-N, Polyurethane, Santoprene, SBR (Red Rubber), Silicone, Skirtboard, Sponge Rubber, Urethane, Viton® and White FDA Neo/Buna. The insert 4 may comprise through-holes 45 (eg. Circular) configured to allow plasma to pass through the insert. The first material should be compatible with the plasma processing.

Alternatively, as shown in FIG. 5 the insert may comprise a solid plate comprising a plurality of through-holes 45 (e.g. to match the through-holes 11 in the frame 1). In other words, no aperture 5 is provided for accommodating a substrate 5. Instead a substrate 5 may be placed on the insert 4.

The insert 4 may be entirely formed from the first material, for example as shown in FIG. 1. Alternatively, the insert 4 may further comprise an insert frame 42 formed from a second material and configured to support the mask 43, as shown in FIG. 8. As shown in FIG. 8, the insert frame 42 may be formed in two parts 42A, 42B each part associated with a respective insert part 4A, 4B of the insert. The mask 43 may comprise two parts 43A, 43B configured to sandwich the substrate 5 therebetween, each part associated with a respective insert part 4A, 4B of the insert. FIGS. 9A and 9B show parts 43A, 43B of the mask 43. The shapes of the parts 43A, 43B of the mask may be different from each other so different parts of the opposing sides of the substrate 5 can be processed.

Preferably, the second material is a rigid material. The second material may be the same material from which the frame is formed. For example, the second material may be a metal e.g. stainless steel, but preferably aluminium. The insert frame 42 may surround the mask 43, either partially or completely, as viewed from above (in a thickness direction). This mask 43 may be fixed to the frame in a non-releasable manner, e.g. with an adhesive.

The aperture 41 of the insert 4 may comprises a shelf member configured to support the substrate within the aperture 41. The shelf member may be formed by a relatively narrow portion of the aperture 2 such that the substrate 5 is prevented from passing through the aperture 41 beyond the location of the shelf member. The shelf member may be formed by a flat surface on which the substrate 5 can rest. However, this is not essential, e.g. the surface may be sloped relative to the walls of the rest of the aperture. A shelf member may be provided in each of the first and second insert parts 4A, 4B, e.g. closer to the outside surfaces of the constructed insert 4.

The shape of the insert 4 and the shape of the aperture 2 in the frame 1 of the substrate mount should be mutually configured to fit with one another.

It should be understood that variations of the above embodiments and examples are possible within the scope of the invention as defined by the appended claims.

1. A substrate mount for a plasma processing apparatus comprising:
a frame;
an aperture within the frame, configured to accommodate an insert, the insert being configured to support a substrate for processing by the plasma processing apparatus;
a releasable securing mechanism configured to releasably secure the insert within the aperture such that the insert can be replaced.

2. The substrate mount of claim 1, wherein the frame is formed from a single part.

3. The substrate mount of claim 1 wherein the frame comprises first and second frame parts, the first and second frame parts being configured to sandwich the insert therebetween.

4. The substrate mount of claim 3, wherein the releasable securing mechanism is configured to releasably secure the first frame part to the second frame part.

5. The substrate mount according to claim 1, wherein the releasable securing mechanism is configured to releasably secure the insert to the frame.

6. The substrate mount of claim 1 wherein the securing mechanism comprises a spring element configured to provide a securing force.

7. The substrate mount of claim 6, wherein the securing mechanism comprises an abutment member configured to apply the securing force therethrough.

8. The substrate mount of claim 7, wherein the abutment member is also the spring element.

9. The substrate mount of claim 7, wherein the spring element is separate from but connected to the abutment member.

10. (canceled)

11. The substrate mount of claim 1, wherein the releasable securing mechanism is selectably configurable between a first arrangement configured to secure the insert and a second arrangement configured not to secure the insert.

12. The substrate mount of claim 11, wherein the releasable securing mechanism is configured to rotate between the first arrangement and the second arrangement.

13. The substrate mount of claim 11, wherein the releasable securing mechanism is configured to slide linearly between the first arrangement and the second arrangement.

14. (canceled)

15. (canceled)

16. (canceled)

17. (canceled)

18. The substrate mount of claim 1 further comprising an insert comprising an aperture for accommodating the substrate.

19. The substrate mount of claim 18, comprising a first insert part and a second insert part, the first and second insert parts being configured to sandwich the substrate therebetween.

20. The substrate mount of claim 19, comprising an alignment member configured to align the first and second insert parts and, optionally, the substrate.

21. The substrate mount of claim 20, wherein the alignment member is a rod configured to pass through through-holes in each of the first and second insert parts and, optionally, the substrate.

22. The substrate mount of claim 18, comprising a mask formed from a first material and configured to support the substrate such that a portion of the substrate is masked so as not to be processed by the plasma processing apparatus.

23. The substrate mount of claim 22, wherein the first material is a flexible material.

24. The substrate mount of claim 18, further comprising an insert frame formed from a second material and configured to support the mask.

25. The substrate mount of claim 24, wherein the second material is a rigid material.

26. (canceled)

27. (canceled)

28. (canceled)
